(19) United States
(12) Patent Application Publication
(10) Pub. No.: US 2006/0219172 A1
(43) Pub. Date: Oct. 5, 2006

(54) PVD equipment and electrode and deposition ring thereof

(75) Inventors: Yu-Yuan Kuo, Chiayi County (TW); Shuo-Yen Tai, Chiayi County (TW); Chou-Ting Tsai, Kaohsiung City (TW); Ming-Te More, Tainan City (TW); Kuo-Hsien Cheng, Tainan City (TW); G. H. Tseng, Kaohsiung City (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/098,480

(22) Filed: Apr. 5, 2005

(51) Int. Cl. C23C 14/00; C23C 16/00

(52) U.S. Cl. 118/720; 204/298.11; 204/298.15; 118/728

(57) ABSTRACT

A deposition ring comprises a ring body, a groove and a protrusion structure. The ring body is planar-ring shaped, and comprises a first surface. The groove and the protrusion structure are ring shaped and formed on the first surface. The protrusion structure is close to the groove and near an outer side of the ring body. The groove comprises a first side wall, a second side wall and a bottom. A curvature radius of the first side wall is larger than a curvature radius of the second side wall. The second side wall is a continuous ring shaped wall. The bottom is formed between the first side wall and the second side wall.

### BACKGROUND

The invention relates to a deposition ring, and more particularly to a deposition ring for preventing metal from being deposited on a back side of a wafer.

FIG. 1a shows a PVD (physical vapor deposition) electrode 10 comprising a conventional deposition ring 30. Deposition ring 30 is disposed on a base 40. A wafer 20 is disposed on base 40 and an edge thereof is above deposition ring 30. Deposition ring 30 comprises a protrusion structure 31 and a groove 32. As shown in FIG. 1b, which is a top view of deposition ring 30, protrusion structure 31 and groove 32 are ring shaped. Notches 33 are formed on an inner side wall of groove 32.

As shown in FIG. 2a, when conventional deposition ring 30 is utilized in a PVD process, metal deposition 50 is deposited on a back side of wafer 20. For example, with reference to FIG. 2b, which is an enlarged view of portion A in FIG. 2a, TaN layer 52 and Cu layer 51 are deposited on the back side of wafer 20 (the metal deposition on the front and lateral sides of wafer 20 is not discussed hereafter). With reference to FIG. 2a, metal deposition 50 is deposited on the back side of wafer 20 because groove 32 of conventional deposition ring 30 is shallow (about 6 mm). Thus, metal particles from a PVD process are deflected to the back side of wafer 20 after striking a bottom of groove 32. Additionally, metal particles from a PVD process are also deposited on the bottom of groove 32 and form metal deposition 53. With metal deposition 53 growing in groove 32, the speed of metal deposition 50 growing on the back side of wafer 20 increases. Particularly, with reference FIG. 1b, metal deposition 50 grows more serious on the back side of wafer 20 where it corresponds to notches 33 of deposition ring 30.

Metal deposition 50 on the back side of wafer 20 decreases flatness thereof and resolution of subsequent manufacturing processes. Additionally, controlling a thickness of metal deposition 50 is difficult; thus, metal deposition 50 remains after a wet-etching process for same (for example, wet-etching for Cu), and worsens the effectiveness of subsequent wet-etching processes for etching other materials by reacting with subsequent etchant.

### SUMMARY

A deposition ring comprises a ring body, a groove and a protrusion structure. The ring body is planar-ring shaped, and comprises a first surface. The groove and the protrusion structure are ring shaped and formed on the first surface. The protrusion structure is close to the groove and near an outer side of the ring body. The groove comprises a first side wall, a second side wall and a bottom. A curvature radius of the first side wall is larger than a curvature radius of the second side wall. The second side wall is a continuous ring shaped wall. The bottom is formed between the first side wall and the second side wall.

A first angle is formed between the first side wall and the bottom. The first angle is 65 to 120 degrees and preferably 90 degrees. A depth of the groove is 1.2 mm to 3 mm, and preferably 2 mm.

By deepening the groove and modifying the first angle, metal particles from a PVD process are deflected to the second side wall after striking the bottom. Thus, metal deposition is prevented from growing on a back side of the wafer, and process resolution and wet-etching effect are therefore improved. Additionally, the second side wall is a continuous ring shaped wall; thus, metal deposition on the back side of wafer where corresponds to notches of conventional deposition ring is prevented.

### BRIEF DESCRIPTION OF THE DRAWINGS

The invention will become more fully understood from the following detailed description and the accompanying drawings, given by the way of illustration only and thus not intended to limit the disclosure.

FIG. 1a shows a conventional deposition ring disposed on an electrode;

FIG. 1b is a top view of conventional deposition ring;

FIG. 2a shows in conventional metal deposition on a back side of a wafer;

FIG. 2b is an enlarged view of the portion A in FIG. 2a;

FIG. 3a is a cross section view of a deposition ring of the invention;

FIG. 3b is a top view of the deposition ring of the invention;

FIG. 4a shows an electrode of the invention;

FIG. 4b shows metal deposition on a second side wall of the invention;

FIG. 5a shows a groove with lead angles;

FIG. 5b shows a triangle shaped protrusion structure;

FIG. 6 shows a PVD equipment of the invention.

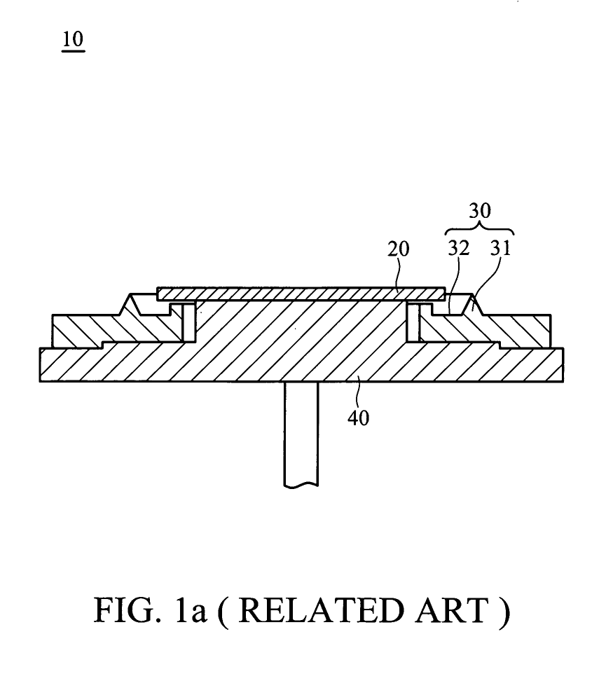

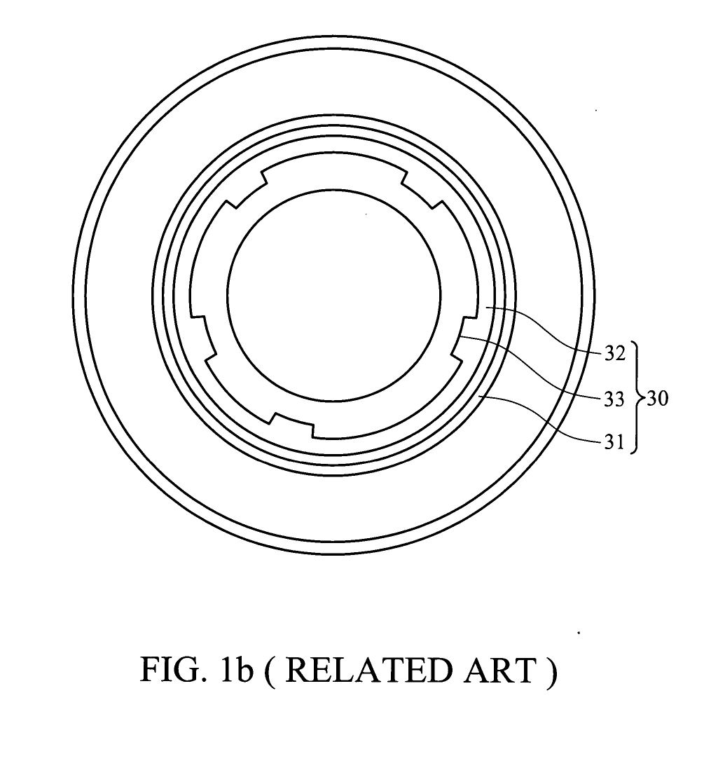

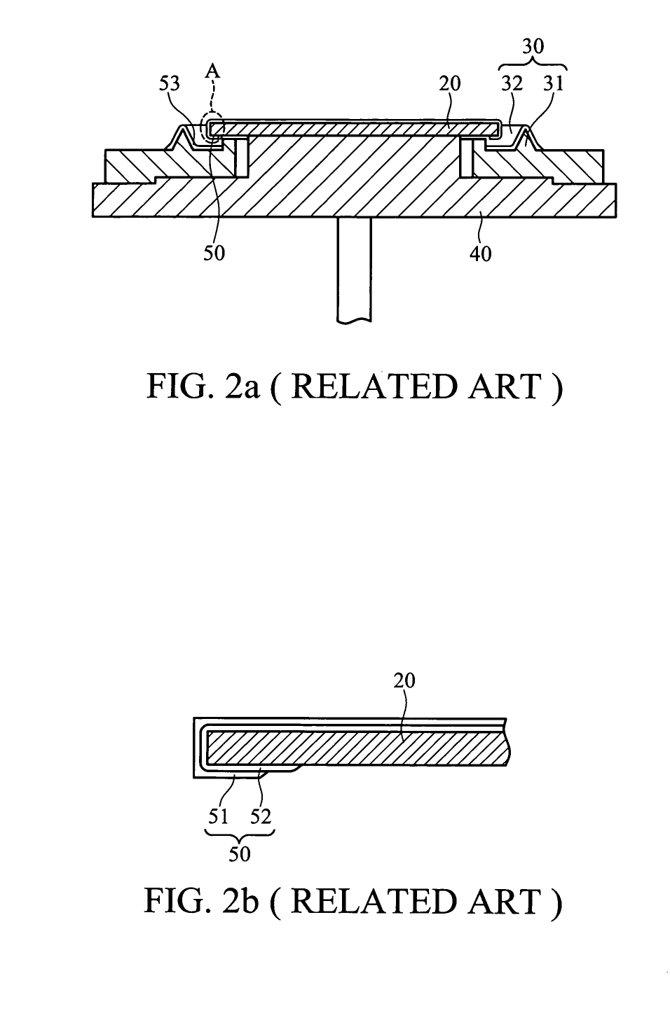

### DETAILED DESCRIPTION

### First Embodiment

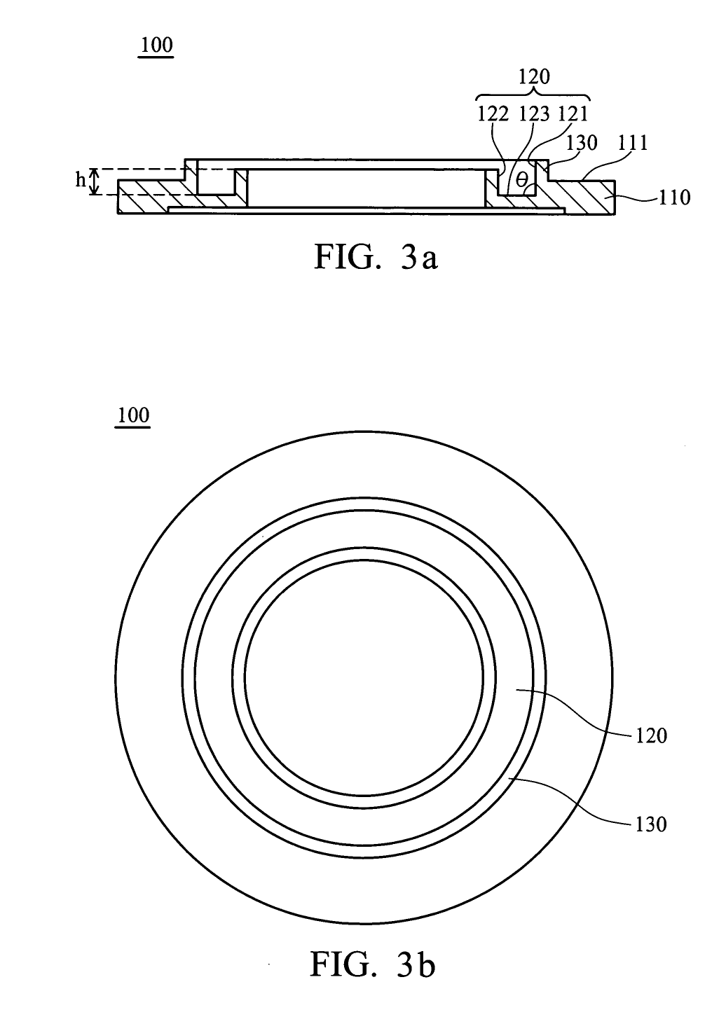

FIG. 3a shows a sectional view of a deposition ring 100 of the invention. With reference FIG. 3b, the deposition ring 100 comprises a ring body 110, a groove 120 and a protrusion structure 130. The ring body 110 is planar-ring shaped, and comprises a first surface 111. The groove 120 and the protrusion structure 130 are ring shaped and formed on the first surface 111. The protrusion structure 130 is close to the groove 120 and near an outer side of the ring body 110. The groove 120 comprises a first side wall 121, a second side wall 122 and a bottom 123. A curvature radius of the first side wall 121 is larger than a curvature radius of the second side wall 122. The second side wall 122 is a continuous ring shaped wall. The bottom 123 is formed between the first side wall 121 and the second side wall 122.

A first angle θ is formed between the first side wall 121 and the bottom 123. The first angle θ is 65 to 120 degrees and preferably 90 degrees. A depth h of the groove 120 (a height of the second side wall 122) is 1.2 mm to 3 mm, and preferably 2 mm.

Material of deposition ring 100 is non-metal and preferably ceramic.

### Second Embodiment

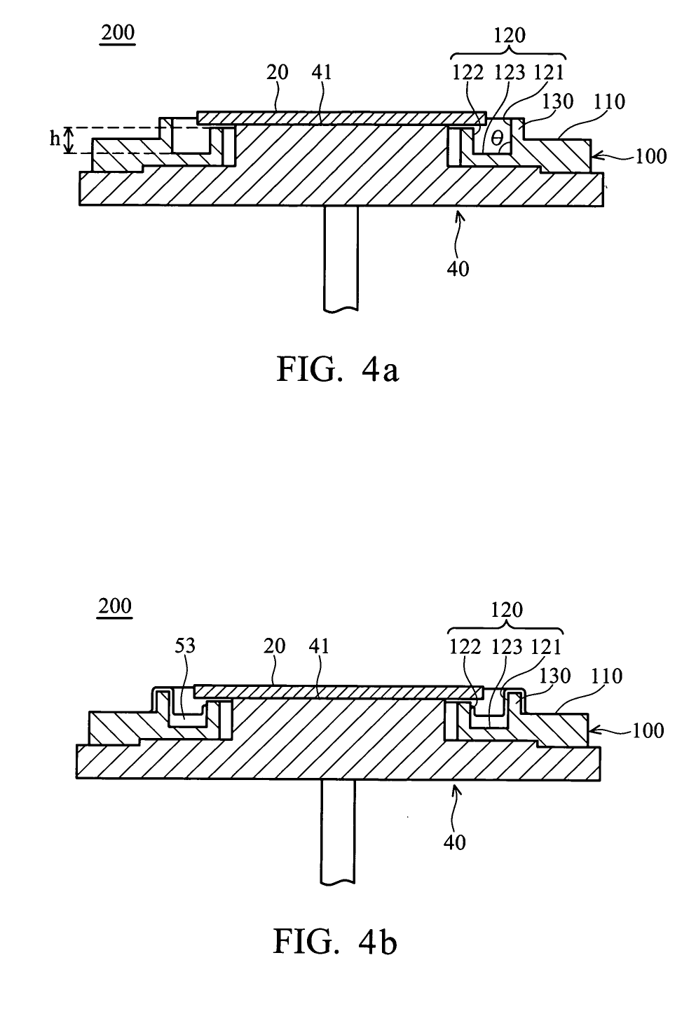

As shown in FIG. 4a, the invention can also be a PVD electrode 200 comprising a base 40 and a deposition ring 100. The base 40 comprises a supporting portion 41 protruding from the center thereof for supporting a wafer 20. The deposition ring 100 is-disposed on the base 40, and surrounds the supporting portion 41. With reference to FIG. 3b, the deposition ring 100 comprises a ring body 110, a groove 120 and a protrusion structure 130. The ring body 110 is planar-ring shaped, and comprises a first surface 111. The groove 120 and the protrusion structure 130 are ring shaped and formed on the first surface 111. The protrusion structure 130 is close to the groove 120 and near an outer side of the ring body 110. The groove 120 comprises a first side wall 121, a second side wall 122 and a bottom 123. A curvature radius of the first side wall 121 is larger than a curvature radius of the second side wall 122. The second side wall 122 is a continuous ring shaped wall. The bottom 123 is formed between the first side wall 121 and the second side wall 122.

A first angle θ is formed between the first side wall 121 and the bottom 123. The first angle θ is 65 to 120 degrees and preferably 90 degrees. A depth h of the groove 120 (a height of the second side wall 122) is 1.2 mm to 3 mm, and preferably 2 mm.

Material of deposition ring 100 is non-metal and preferably ceramic materials.

The PVD electrode 200 is utilized in depositing Cu, Ta or other materials.

As shown in FIG. 4b, by deepening the depth h of the groove 120 and modifying the first angle θ, the metal deposition 53 is deposited on the bottom 123, and metal particles from a PVD process are deflected to the second side wall 122 after striking the bottom 123. Thus, metal deposition is prevented from growing on a back side of the wafer 20, and process resolution and wet-etching effect are therefore improved. Additionally, the second side wall 122 is a continuous ring shaped wall; thus, metal deposition on the back side of the wafer where it corresponds to notches a of conventional deposition ring is also prevented.

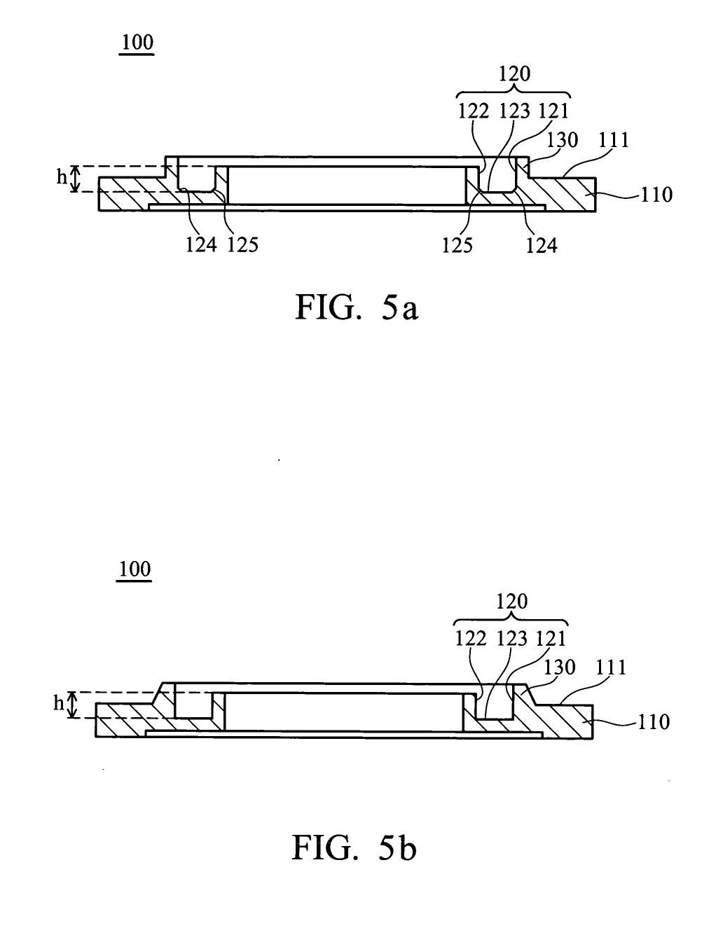

Shapes of the protrusion structure 130 or groove 120 can be modified. The modifications, however, are also included in a scope of the invention. For example, as shown in FIG. 5a, lead angle 124 is formed between the first side wall 121 and the bottom 123, and lead angle 125 is formed between the second side wall 122 and the bottom 123. The lead angles can also be replaced by rounds. Or, as shown in FIG. 5b, a cross section of the protrusion structure 130 is modified to a triangular shape.

### Third Embodiment

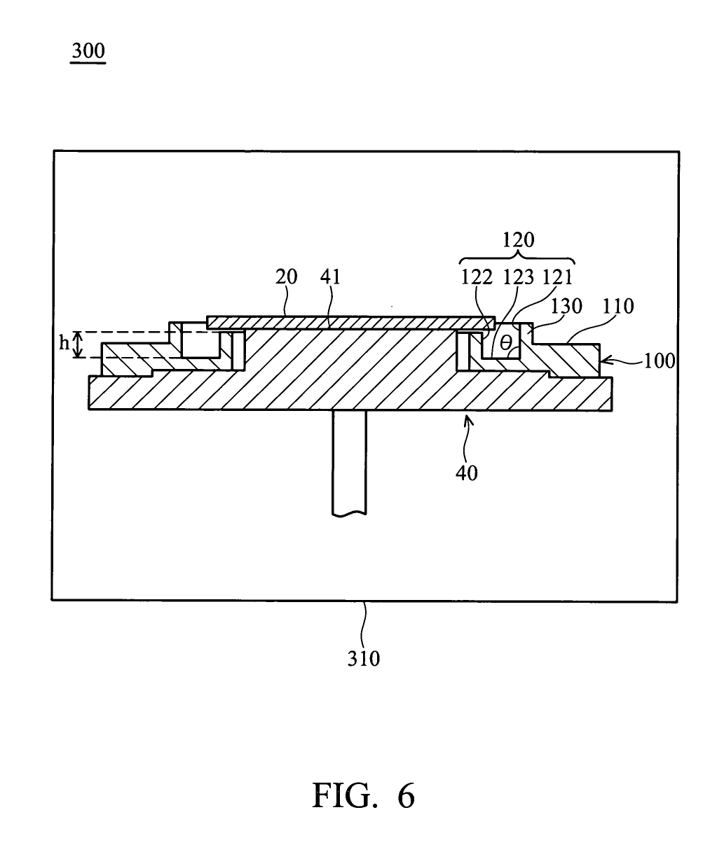

As shown in FIG. 6, the invention can also be a PVD equipment 300 which comprises a chamber 310, a base 40 and a deposition ring 100. The base 40 is disposed in the chamber 310, and comprises a supporting portion 41 protruding from the center thereof for supporting a wafer 20. The deposition ring 100 is disposed on the base 40, and surrounds the supporting portion 41. With reference to FIG. 3b, the deposition ring 100 comprises a ring body 110, a groove 120 and a protrusion structure 130. The ring body 110 is planar-ring shaped, and comprises a first surface 111. The groove 120 and the protrusion structure 130 are ring shaped and formed on the first surface 111. The protrusion structure 130 is close to the groove 120 and near an outer side of the ring body 110. The groove 120 comprises a first side wall 121, a second side wall 122 and a bottom 123. A curvature radius of the first side wall 121 is larger than a curvature radius of the second side wall 122. The second side wall 122 is a continuous ring shaped wall. The bottom 123 is formed between the first side wall 121 and the second side wall 122.

A first angle θ is formed between the first side wall 121 and the bottom 123. The first angle θ is 65 to 120 degrees and preferably 90 degrees. A depth h of the groove 120 (a height of the second side wall 122) is 1.2 mm to 3 mm, and preferably 2 mm.

Material of deposition ring 100 is non-metal and preferably ceramic.

The PVD equipment 300 is utilized in depositing Cu, Ta or other materials which utilize evaporation or sputtering in the deposition process, particularly DC sputtering, magnetron DC sputtering, collimator, long throw and ionized sputtering.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A deposition ring, comprising:
a ring body, which is planar-ring shaped, comprising a first surface; and
a groove, formed on the first surface,
wherein the groove is ring shaped, near an inner side of the ring body, and a depth of the groove is between 1.2 mm and 3 mm.

2. The deposition ring as claimed in claim 1, wherein the depth of the groove is 2 mm.

3. The deposition ring as claimed in claim 1, wherein the groove comprises a first side wall, a second side wall and a bottom, the bottom is formed between the first side wall and the second side wall, and a curvature radius of the first side wall is larger than a curvature radius of the second side wall.

4. The deposition ring as claimed in claim 3, wherein a first angle is formed between the first side wall and the bottom, and the first angle is between 65 degrees and 120 degrees.

5. The deposition ring as claimed in claim 4, wherein the first angle is 90 degrees.

6. The deposition ring as claimed in claim 3, wherein the second wall is a continuous ring-shaped wall.

7. The deposition ring as claimed in claim 3, wherein the deposition ring is a non-metal material.

8. The deposition ring as claimed in claim 7, wherein the deposition ring is a ceramic material.

9. The deposition ring as claimed in claim 1, further comprising a ring shaped protrusion structure, disposed on the first surface close to the groove, and near an outer side of the ring body.

10. A PVD electrode, comprising:
a base; and
a deposition ring, disposed on the base, comprising a ring body and a groove, wherein the ring body is planar-ring shaped, and comprises a first surface,
wherein the groove is ring shaped near an inner side of the ring body, and a depth of the groove is between 1.2 mm and 3 mm.

11. The PVD electrode as claimed in claim 10, wherein the depth of the groove is 2 mm.

12. The PVD electrode as claimed in claim 10, wherein the groove comprises a first side wall, a second side wall and a bottom, the bottom is formed between the first side wall and the second side wall, and a curvature radius of the first side wall is larger than a curvature radius of the second side wall.

13. The PVD electrode as claimed in claim 12, wherein a first angle is formed between the first side wall and the bottom, and the first angle is between 65 degrees and 120 degrees.

14. The PVD electrode as claimed in claim 12, wherein the second wall is a continuous ring shaped wall.

15. The PVD electrode as claimed in claim 12, wherein the deposition ring is a non-metal material.

16. A PVD equipment, comprising:
a chamber;
a base, disposed in the chamber; and
a deposition ring, disposed on the base, comprising a ring body and a groove, wherein the ring body is planar-ring shaped, and comprises a first surface,
wherein the groove is ring shaped, near an inner side of the ring body, and a depth of the groove is between 1.2 mm and 3 mm.

17. The PVD equipment as claimed in claim 16, wherein the depth of the groove is 2 mm.

18. The PVD equipment as claimed in claim 16, wherein the groove comprises a first side wall, a second side wall and a bottom, the bottom is formed between the first side wall and the second side wall, and a curvature radius of the first side wall is larger than a curvature radius of the second side wall.

19. The PVD equipment as claimed in claim 18, wherein a first angle is formed between the first side wall and the bottom, and the first angle is between 65 degrees and 120 degrees.

20. The PVD equipment as claimed in claim 18, wherein the deposition ring is a non-metal material.
